(19) United States
(12) Patent Application Publication
(10) Pub. No.: US 2007/0208520 A1
(43) Pub. Date: Sep. 6, 2007

(54) Systems, devices, and methods for arc fault management

(75) Inventors: Bin Zhang, Alpharetta, GA (US); Carlos Restrepo, Atlanta, GA (US); Mikhail Golod, Alpharetta, GA (US); Sandra Shields, Doraville, GA (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Energy & Automation, Inc.

(21) Appl. No.: 11/365,714

(22) Filed: Mar. 1, 2006

(51) Int. Cl. G01R 31/00

(52) U.S. Cl. 702/58; 702/1; 702/57; 702/64; 702/108

(57) ABSTRACT

Certain exemplary embodiments can comprise a fault detection system, which can comprise a microprocessor. The microprocessor can be configured to automatically generate an output signal to an output pin responsive to an input signal indicative of an arc fault. The output signal can be configured to trip a circuit breaker.

### BACKGROUND

U.S. Pat. No. 6,421,214 (Packard), which is incorporated by reference herein in its entirety, allegedly recites a “self-testing arc fault or ground fault detector includes arc fault detecting circuitry and components. The detector includes a testing circuit which tests at least part of the circuitry and components and generates a recurring signal when the test completes successfully. If the test does not complete successfully, the signal is lost. This loss of signal is signaled by an indicator connected to the testing circuit. In one version, the loss of signal activates a circuit interrupter which disconnects the load side of the detector from the line side.” See Abstract.

U.S. Pat. No. 6,477,021 (Haun), which is incorporated by reference herein in its entirety, allegedly recites a “system for determining whether arcing is present in an electrical circuit includes a sensor for monitoring a current waveform in the electrical circuit, and an arc fault detection circuit which determines whether an arc fault is present in response to the sensor. The arc fault detection circuit includes a controller which produces a trip signal in response to a determination that an arcing fault is present in the electrical circuit, and an inhibit/blocking function for preventing the production of the trip signal under one or more predetermined conditions.” See Abstract.

U.S. Pat. No. 6,532,139 (Kim), which is incorporated by reference herein in its entirety, allegedly recites a “circuit breaker for shutting off an AC electrical source from a phase wire and a neutral wire has the ability to detect an arc fault, ground fault and overload. The circuit breaker includes an arc fault circuit interrupter (AFCI), a ground fault circuit interrupter (GFCI), an overload circuit interrupter (OLCI), and trip circuitry. The AFCI, the GFCI and the OLCI are crossed between the phase wire and the neutral wire of the AC power line and detect the arc fault, ground fault and overload respectively. The trip circuitry is used for shutting off the AC source from the circuit breaker when at least one of the arc fault, ground fault and overload occurs. The circuit breaker is shut when the level of at least one of an arc fault trip signal, ground fault trip signal and overload trip signal is larger than a specified reference trip level.” See Abstract.

### SUMMARY

Certain exemplary embodiments comprise a fault detection system, which can comprise a microprocessor. The microprocessor can be configured to automatically generate an output signal to an output pin responsive to an input signal indicative of an arc fault. The output signal can be configured to trip a circuit breaker.

### BRIEF DESCRIPTION OF THE DRAWINGS

A wide variety of potential practical and useful embodiments will be more readily understood through the following detailed description of certain exemplary embodiments, with reference to the accompanying exemplary drawings in which:

FIG. 1 is a block diagram of an exemplary embodiment of a system 1000;

FIG. 2A is a block diagram of an exemplary embodiment of an arc fault signal conditioning circuit 2000;

FIG. 2B is an exemplary arc fault signal conditioning circuit input waveform;

FIG. 2C is an exemplary arc fault signal conditioning circuit input waveform;

FIG. 2D is an exemplary arc fault signal conditioning circuit output waveform;

FIG. 3 is a graph 3000 of an exemplary embodiment of waveforms associated with an arc fault signal conditioning circuit;

FIG. 4A is a block diagram of an exemplary embodiment of a ground fault signal conditioning circuit 4000;

FIG. 4B is an exemplary ground fault signal conditioning circuit input waveform 4100;

FIG. 4C is an exemplary ground fault signal conditioning circuit output waveform 4200;

FIG. 5 is a graph 5000 of an exemplary embodiment of a simulated arc waveform;

FIG. 6 is a flowchart of an exemplary embodiment of a method 6000;

FIG. 7 is a flowchart of an exemplary embodiment of a method 7000; and

FIG. 8 is a block diagram of an exemplary embodiment of an information device 8000.

### DEFINITIONS

When the following terms are used substantively herein, the accompanying definitions apply:
a—at least one.
activity—an action, act, step, and/or process or portion thereof.
adapted to—made suitable or fit for a specific use or situation.
amplifier—a device that increases strength of signals passing through it.
analog—a signal formed from continuous measurement and/or input.
analog to digital converter—a device configured to receive an analog input and generate a digital output related to the analog input.
and/or—either in conjunction with or in alternative to.
apparatus—an appliance or device for a particular purpose.
approximately—nearly the same as.
arc fault—a discharge of electricity between two or more conductors, the discharge associated with at least a predetermined voltage, current, and/or power level.
associated with—related to.
automatically—acting or operating in a manner essentially independent of external influence or control. For example, an automatic light switch can turn on upon “seeing” a person in its view, without the person manually operating the light switch.
automatically—acting or operating in a manner essentially independent of external influence or control. For example, an automatic light switch can turn on upon “seeing” a person in its view, without the person manually operating the light switch.
calibrate—to check, adjust, and/or determine by comparison with a standard.
can—is capable of, in at least some embodiments.
circuit—an electrically conducting pathway.
circuit breaker—a device adapted to automatically open an alternating current electrical circuit.
code—machine-readable instructions.
comprising—including but not limited to.
configured to—capable of performing a particular function.
correct—to change to a more desired value.
corruption—a state of being altered from a desired form.
current—a flow of electrical energy.
data—distinct pieces of information, usually formatted in a special or predetermined way and/or organized to express concepts.
dedicate—to commit and/or give entirely to a particular use, activity, cause, and/or entity.
define—to establish the outline, form, or structure of.
detect—to sense, perceive, and/or identify.
device—a machine, manufacture, and/or collection thereof.
differential current—a difference between a first flow of electrical charge involving a first electrical conductor and second flow of electrical charge involving a second electrical conductor.
digital—non-analog; discrete.
direct current (DC)—a non-alternating electric current.
duty cycle—a percentage of time that a pulse train is at a high logic state.
electrical—pertaining to electricity.
electrically coupled—connected in a manner adapted to transfer electrical energy.
energy—usable power.
fault—an arc fault or a ground fault.
fewer—less in number compared to a reference.
gain—an increase or decrease in signal power, voltage, and/or current, expressed as the ratio of output to input.
generate—to create and/or bring into being.
ground fault—a shorting of an electrical device or circuit to ground.
haptic—involving the human sense of kinesthetic movement and/or the human sense of touch. Among the many potential haptic experiences are numerous sensations, body-positional differences in sensations, and time-based changes in sensations that are perceived at least partially in non-visual, non-audible, and non-olfactory manners, including the experiences of tactile touch (being touched), active touch, grasping, pressure, friction, traction, slip, stretch, force, torque, impact, puncture, vibration, motion, acceleration, jerk, pulse, orientation, limb position, gravity, texture, gap, recess, viscosity, pain, itch, moisture, temperature, thermal conductivity, and thermal capacity.
indicative—serving to indicate.
indicator—a signal for attracting attention.
information device—any device capable of processing information, such as any general purpose and/or special purpose computer, such as a personal computer, workstation, server, minicomputer, mainframe, supercomputer, computer terminal, laptop, wearable computer, and/or Personal Digital Assistant (PDA), mobile terminal, Bluetooth device, communicator, “smart” phone (such as a Treo-like device), messaging service (e.g., Blackberry) receiver, pager, facsimile, cellular telephone, a traditional telephone, telephonic device, a programmed microprocessor or microcontroller and/or peripheral integrated circuit elements, an ASIC or other integrated circuit, a hardware electronic logic circuit such as a discrete element circuit, and/or a programmable logic device such as a PLD, PLA, FPGA, or PAL, or the like, etc. In general any device on which resides a finite state machine capable of implementing at least a portion of a method, structure, and/or graphical user interface described herein may be used as an information device. An information device can comprise components such as one or more network interfaces, one or more processors, one or more memories containing instructions, and/or one or more input/output (I/O) devices, one or more user interfaces coupled to an I/O device, etc.
input—related to electricity entering a device.
input/output (I/O) device—any sensory-oriented input and/or output device, such as an audio, visual, haptic, olfactory, and/or taste-oriented device, including, for example, a monitor, display, projector, overhead display, keyboard, keypad, mouse, trackball, joystick, gamepad, wheel, touchpad, touch panel, pointing device, microphone, speaker, video camera, camera, scanner, printer, haptic device, vibrator, tactile simulator, and/or tactile pad, potentially including a port to which an I/O device can be attached or connected.
light emitting diode (LED)—a type of diode that emits light when current passes through it.
machine instructions—directions adapted to cause a machine, such as an information device, to perform a particular operation or function.
machine readable medium—a physical structure from which a machine can obtain data and/or information. Examples include a memory, punch cards, etc.
manage—to direct or control.
may—is allowed and/or permitted to, in at least some embodiments.
measure—to determine a value of something relative to a standard.
memory device—an apparatus capable of storing analog or digital information, such as instructions and/or data. Examples include a non-volatile memory, volatile memory, Random Access Memory, RAM, Read Only Memory, ROM, flash memory, magnetic media, a hard disk, a floppy disk, a magnetic tape, an optical media, an optical disk, a compact disk, a CD, a digital versatile disk, a DVD, and/or a raid array, etc. The memory device can be coupled to a processor and/or can store instructions adapted to be executed by processor, such as according to an embodiment disclosed herein.
method—a process, procedure, and/or collection of related activities for accomplishing something.
microprocessor—an integrated circuit that comprises a central processing unit.
network—a communicatively coupled plurality of nodes. A network can be and/or utilize any of a wide variety of sub-networks, such as a circuit switched, public-switched, packet switched, data, telephone, telecommunications, video distribution, cable, terrestrial, broadcast, satellite, broadband, corporate, global, national, regional, wide area, backbone, packet-switched TCP/IP, Fast Ethernet, Token Ring, public Internet, private, ATM, multi-domain, and/or multi-zone sub-network, one or more Internet service providers, and/or one or more information devices, such as a switch, router, and/or gateway not directly connected to a local area network, etc.
network interface—any device, system, or subsystem capable of coupling an information device to a network. For example, a network interface can be a telephone, cellular phone, cellular modem, telephone data modem, fax modem, wireless transceiver, Ethernet card, cable modem, digital subscriber line interface, bridge, hub, router, or other similar device.
obtain—to receive, calculate, determine, and/or compute.
output—something produced, and/or generated.
packet—a discrete instance of communication.
pin—an electrically conductive appendage of a microprocessor.
plurality—the state of being plural and/or more than one.
power supply—a source of electrical energy.
predetermined—established in advance.
prevent—to keep an event from happening.
processor—a device and/or set of machine-readable instructions for performing one or more predetermined tasks. A processor can comprise any one or a combination of hardware, firmware, and/or software. A processor can utilize mechanical, pneumatic, hydraulic, electrical, magnetic, optical, informational, chemical, and/or biological principles, signals, and/or inputs to perform the task(s). In certain embodiments, a processor can act upon information by manipulating, analyzing, modifying, converting, transmitting the information for use by an executable procedure and/or an information device, and/or routing the information to an output device. A processor can function as a central processing unit, local controller, remote controller, parallel controller, and/or distributed controller, etc. Unless stated otherwise, the processor can be a general-purpose device, such as a microcontroller and/or a microprocessor, such the Pentium IV series of microprocessor manufactured by the Intel Corporation of Santa Clara, Calif. In certain embodiments, the processor can be dedicated purpose device, such as an Application Specific Integrated Circuit (ASIC) or a Field Programmable Gate Array (FPGA) that has been designed to implement in its hardware and/or firmware at least a part of an embodiment disclosed herein.
provide—to furnish and/or supply.
range—a measure of an extent of a set of values.
receive—to take, get, acquire, and/or have bestowed upon.
relative—in comparison with.
render—make perceptible to a human, for example as data, commands, text, graphics, audio, video, animation, and/or hyperlinks, etc., such as via any visual, audio, and/or haptic means, such as via a display, monitor, electric paper, ocular implant, cochlear implant, speaker, etc.
repeatedly—again and again; repetitively.
request—(n.) a message asking for something.
request—(v.) to ask for something.
resistive current sensor—a device configured to measure an electrical flow via a voltage drop across a resistor.
resistor—a device used to control current in an electric circuit by impeding a flow of electrons.
responsive—reacting to an influence and/or impetus.
run status—an indication of operation or non-operation.
sensor—a device or system adapted to detect or perceive automatically.
set—a related plurality.
signal—detectable transmitted energy, such as an impulse or a fluctuating electric quantity, such as voltage, current, or electric field strength.
simulate—to create as a representation or model of another thing.
single—one item.
store—to place, hold, and/or retain data, typically in a memory.
substantially—to a great extent or degree.
system—a collection of mechanisms, devices, data, and/or instructions, the collection designed to perform one or more specific functions.
temperature—measure of the average kinetic energy of the molecules in a sample of matter, expressed in terms of units or degrees designated on a standard scale.
trip—(n.) an opening of an electrical circuit that interrupts current flow in the electrical circuit.
trip—(v.) to open an electrical circuit; to automatically interrupt current flow in an electrical circuit.
user—any person, process, device, program, protocol, and/or system that uses a device.
user interface—any device for rendering information to a user and/or requesting information from the user. A user interface includes at least one of textual, graphical, audio, video, animation, and/or haptic elements. A textual element can be provided, for example, by a printer, monitor, display, projector, etc. A graphical element can be provided, for example, via a monitor, display, projector, and/or visual indication device, such as a light, flag, beacon, etc. An audio element can be provided, for example, via a speaker, microphone, and/or other sound generating and/or receiving device. A video element or animation element can be provided, for example, via a monitor, display, projector, and/or other visual device. A haptic element can be provided, for example, via a very low frequency speaker, vibrator, tactile stimulator, tactile pad, simulator, keyboard, keypad, mouse, trackball, joystick, gamepad, wheel, touchpad, touch panel, pointing device, and/or other haptic device, etc. A user interface can include one or more textual elements such as, for example, one or more letters, number, symbols, etc. A user interface can include one or more graphical elements such as, for example, an image, photograph, drawing, icon, window, title bar, panel, sheet, tab, drawer, matrix, table, form, calendar, outline view, frame, dialog box, static text, text box, list, pick list, pop-up list, pull-down list, menu, tool bar, dock, check box, radio button, hyperlink, browser, button, control, palette, preview panel, color wheel, dial, slider, scroll bar, cursor, status bar, stepper, and/or progress indicator, etc. A textual and/or graphical element can be used for selecting, programming, adjusting, changing, specifying, etc. an appearance, background color, background style, border style, border thickness, foreground color, font, font style, font size, alignment, line spacing, indent, maximum data length, validation, query, cursor type, pointer type, autosizing, position, and/or dimension, etc. A user interface can include one or more audio elements such as, for example, a volume control, pitch control, speed control, voice selector, and/or one or more elements for controlling audio play, speed, pause, fast forward, reverse, etc. A user interface can include one or more video elements such as, for example, elements controlling video play, speed, pause, fast forward, reverse, zoom-in, zoom-out, rotate, and/or tilt, etc. A user interface can include one or more animation elements such as, for example, elements controlling animation play, pause, fast forward, reverse, zoom-in, zoom-out, rotate, tilt, color, intensity, speed, frequency, appearance, etc. A user interface can include one or more haptic elements such as, for example, elements utilizing tactile stimulus, force, pressure, vibration, motion, displacement, temperature, etc.
value—an assigned or calculated numerical quantity.
via—by way of and/or utilizing.
voltage—a difference in electrical potential between any two conductors of an electrical circuit.

### DETAILED DESCRIPTION

Certain exemplary embodiments provide a fault detection system, which can comprise a microprocessor. The microprocessor can be configured to automatically generate an output signal to an output pin responsive to an input signal indicative of an arc fault. The output signal can be configured to trip a circuit breaker.

Certain exemplary embodiments provide a method to detect arc faults and ground faults in low voltage Alternating Current (AC) power distribution systems. The method can utilize a hardware, firmware, and/or software. The method can be based on a system that comprises a microprocessor and/or a Digital Signal Processor (DSP). In certain exemplary embodiments, hardware can be simplified for relatively low cost applications and can be characterized by a relatively compact size. The method can comprise arc fault and/or ground fault detection, calibration, simulated arc and/or ground fault signal generation for circuit tests, and/or temperature compensation, etc.

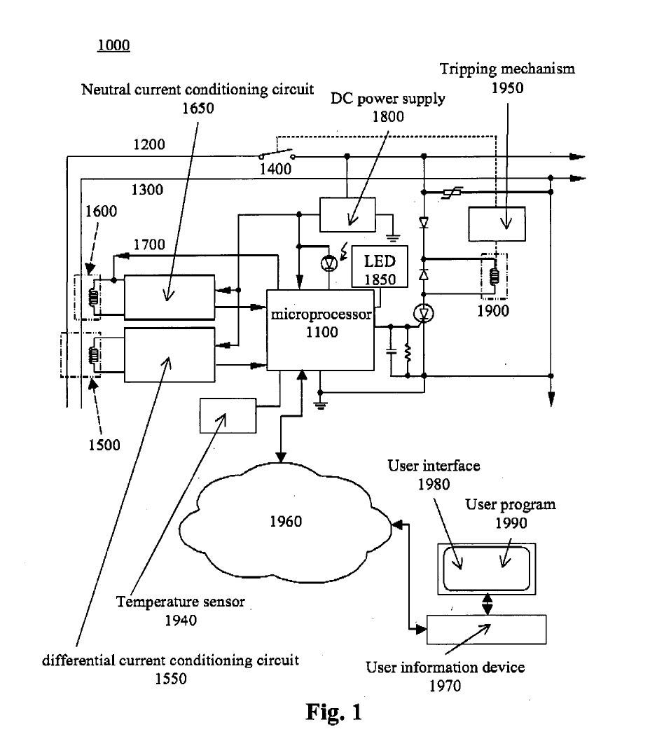

FIG. 1 is a block diagram of an exemplary embodiment of a system 1000, which can comprise an arc fault and/or ground fault detector comprised in a single-chip microprocessor 1100. In certain exemplary embodiments, single-chip microprocessor 1100 can be a Digital Signal Processor (DSP). In certain exemplary embodiments, single-chip microprocessor 1100 can be a single-circuit breaker dedicated microprocessor.

A current sensor 1600 used on a neutral conductor 1300 can be configured to provide a signal for use in arc fault monitoring. A signal from current sensor 1600 can be conditioned via a neutral current conditioning circuit 1650. A differential current sensor 1500, used to measure a differential current between neutral conductor 1300 and a line conductor 1200, can provide a signal for use in ground fault monitoring. In certain exemplary embodiments, differential current sensor 1500 and/or current sensor 1600 can be resistive current sensors. A signal from differential current sensor 1500 can be conditioned via a differential current conditioning circuit 1550. Signals from neutral current conditioning circuit 1650 and/or differential current conditioning circuit 1550 can be provided to single-chip microprocessor 1100. Single-chip microprocessor 1100 can be configured to receive an input signal indicative of an arc fault from current sensor 1600. Single-chip microprocessor 1100 can be configured to receive an input signal indicative of a ground fault from differential current sensor 1500.

Single-chip microprocessor 1100 can be configured to condition and/or amplify an input signal, detect an arc fault, detect a ground fault, regulate a voltage, test one or more components in system 1000 responsive to a simulated arc fault signal 1700, reset a fault detection counter during power up, compensate for a temperature variation of current sensor 1600 and/or differential current sensor 1500, and/or control circuit breaker trip functions, provide fault and/or error notifications and/or alerts, etc. In certain exemplary embodiments, single-chip microprocessor 1100 can comprise a multi channel on-chip Analog to Digital (A/D) converter. The multi channel on-chip A/D converter can be configured to accept an analog input from current sensor 1600 and/or differential current sensor 1500 and can provide a digital output to other circuits comprised in single-chip microprocessor 1100. Single-chip microprocessor 1100 can be configured to generate simulated arc fault signal 1700, which can be provided to an input pin of single-chip microprocessor 1100 for system testing purposes. In certain exemplary embodiments, system 1000 can comprise a mechanical button configured, when depressed, to initiate a system test, which can comprise generating simulated arc fault signal 1700. In certain exemplary embodiments, system 1000 can comprise a non-volatile memory, which can be comprised in a memory device associated with single-chip microprocessor 1100.

Digital inputs to single-chip microprocessor 1100, such as from a network-connected information device and/or from a user interface, can be used to activate or select one or more system functions. For example, a switching signal (ON or OFF) can be utilized to enable or disable simulated arc fault signal 1700. As another example, a calibration procedure can be activated. In certain exemplary embodiments, single-chip microprocessor 1100 can be configured to automatically calibrate current sensor 1600 and/or differential current sensor 1500. In certain exemplary embodiments, single-chip microprocessor 1100 can be configured to receive a user request to calibrate current sensor 1600 and/or differential current sensor 1500. In such embodiments, single-chip microprocessor 1100 can calibrate current sensor 1600 and/or differential current sensor 1500 responsive to the user request. In certain exemplary embodiments, single-chip microprocessor 1100 can be configured to automatically calibrate a gain of an analog to digital converter electrically coupled to current sensor 1600.

In certain exemplary embodiments, a temperature sensor 1940 can be comprised in and/or electrically coupled to single-chip microprocessor 1100. Temperature sensor 1940 can be configured to provide a temperature value for correcting a measured value of current sensor 1600 and/or differential current sensor 1500. Temperature sensor 1940 can be comprised in and/or electrically coupled to single-chip microprocessor 1100. In certain exemplary embodiments, single-chip microprocessor 1100 can be configured to automatically correct a value obtained from current sensor 1500 and/or differential current sensor 1500. In certain exemplary embodiments, single-chip microprocessor 1100 can be configured to detect corruption in code comprised in single-chip microprocessor 1100. The code can be associated with, and/or configured to generate, an output signal from single-chip microprocessor 1100 that provides instructions to open a switch to stop a flow of an electrical current in a circuit monitored by single-chip microprocessor 1100.

System 1000 can comprise a DC power supply 1800 with a signal voltage output and a current capacitance. DC power supply 1800 can be configured to provide electrical energy to single-chip microprocessor 1100. In certain exemplary embodiments, power consumption in system 1000 can be relatively low.

In certain exemplary embodiments, single-chip microprocessor 1100 can be configured to automatically generate an output signal to an output pin responsive to an input signal indicative of a fault. In certain exemplary embodiments, the output signal can be configured to trip a single circuit breaker. Single-chip microprocessor 1100 can be configured to generate a tripping control signal if an arc fault or ground fault is detected, which can drive a device such as a solenoid 1900, which can be adapted to trip an electrical circuit associated with system 1000. For example, solenoid 1900 can be configured to actuate a mechanical tripping mechanism 1950 to disconnect the power to the load via, for example, SCR and/or solenoid 1900, causing a switch 1400 to open.

A Light Emitting Diode (LED) 1850 indicator can be electrically coupled to a digital output of single-chip microprocessor 1100. LED 1850 can be used to indicate a run status of single-chip microprocessor 1100. Any predetermined change, or set of changes, in LED 1850 can be related to any predetermined status of system 1000. Examples that follow are intended to be illustrative and not restrictive in their description of possible indications of status. In certain exemplary embodiments, if LED 1850 is OFF, an inference can be made that system power has been lost. In certain exemplary embodiments, if LED 1850 is ON, an inference can be made that system power is on, but single-chip microprocessor 1100 is not running. In certain exemplary embodiments, if LED 1850 is blinking at a constant visible rate, an inference can be made that single-chip microprocessor 1100 is running normally. In certain exemplary embodiments, if LED 1850 is blinking at an inconsistent rate, an inference can be made that single-chip microprocessor 1100 has detected a fault.

Single-chip microprocessor 1100 can be communicatively coupled to a network 1960. In certain exemplary embodiments, single-chip microprocessor 1100 can comprise a wireless transceiver, which can wirelessly transmit signals via network 1960. Via network 1960, single-chip microprocessor 1100 can be communicatively coupled to an information device 1970. Information device 1970 can comprise a user interface 1980 and/or a user program 1990. Information device 1970 can be configured to receive, process, and/or render information obtained from single-chip microprocessor 1100 related to fault detection and/or diagnostic testing related to system 1000. User program 1990 can be configured to analyze fault and/or diagnostic information. User interface 1980 can be configured to render information regarding system 1000 for a user.

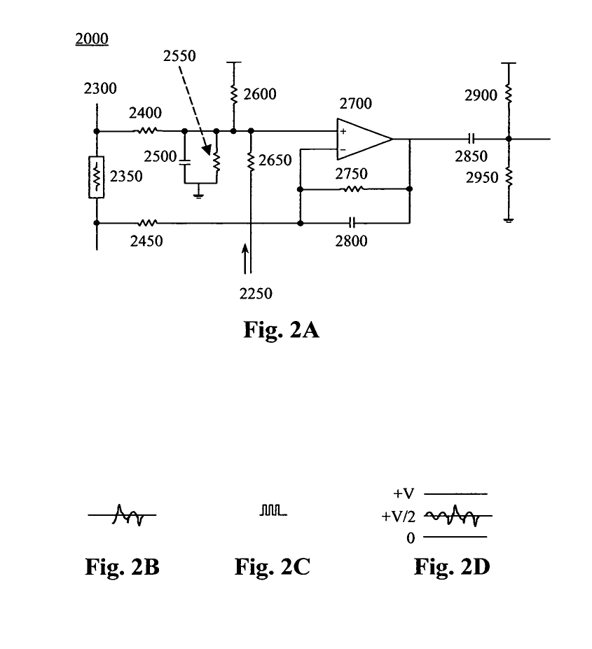

FIG. 2A is a block diagram of an exemplary embodiment of an arc fault signal conditioning circuit 2000, which can be configured to receive an input signal, such as an exemplary input signal as illustrated in FIG. 2B, from a current sensor 2350. Current sensor 2350 can be configured to measure an electrical current on a neutral conductor 2300. Arc fault signal conditioning circuit 2000 can be configured to receive differential inputs from current sensor 2350, which can provide a relatively accurate signal input and relatively good noise immunization. A simulated input 2250, such as an exemplary input signal as illustrated in FIG. 2C, can be provided to arc fault signal conditioning circuit 2000 by a microprocessor.

Arc fault signal conditioning circuit 2000 can comprise a signal voltage amplifier 2700. Signal voltage amplifier 2700 can be configured to amplify an analog signal from current sensor 2350. Amplifier 2700 can be electrically coupled to the microprocessor.

Arc fault signal conditioning circuit 2000 can comprise a plurality of resistors such as resistor 2400, resistor 2450, resistor 2550, resistor 2600, resistor 2650, resistor 2750, resistor 2900, and/or resistor 2950, each of which can be selected and sized to set a gain of amplifier 2700, to match impedance from both positive and negative inputs of amplifier 2700, and/or to set an offset voltage of a signal output into a center of a predetermined DC voltage range. The output, such as an exemplary output signal as illustrated in FIG. 2D, can be provided to an analog input of a microprocessor and/or a DSP. The microprocessor and/or DSP can be configured to perform an analog to digital conversion of signal output 2200.

Arc fault signal conditioning circuit 2000 can comprise a plurality of capacitors such as capacitor 2500 and/or capacitor 2800, which can be selected and/or sized to set a frequency response of arc fault signal conditioning circuit 2000 to control a gain of a high frequency signal. The gain in the high frequency signal can be interpreted as noise in an arc fault detection scheme. A capacitor 2850 can be selected and/or sized to provide a relatively low signal offset error. A digital square wave output from the microprocessor and/or DSP can be used to simulate an arc input to test the function of a system comprising arc fault signal conditioning circuit 2000 from amplifier 2700 to a mechanical tripping mechanism associated with arc fault signal conditioning circuit 2000.

FIG. 2B is an exemplary arc fault signal conditioning circuit input waveform.

FIG. 2C is an exemplary arc fault signal conditioning circuit input waveform.

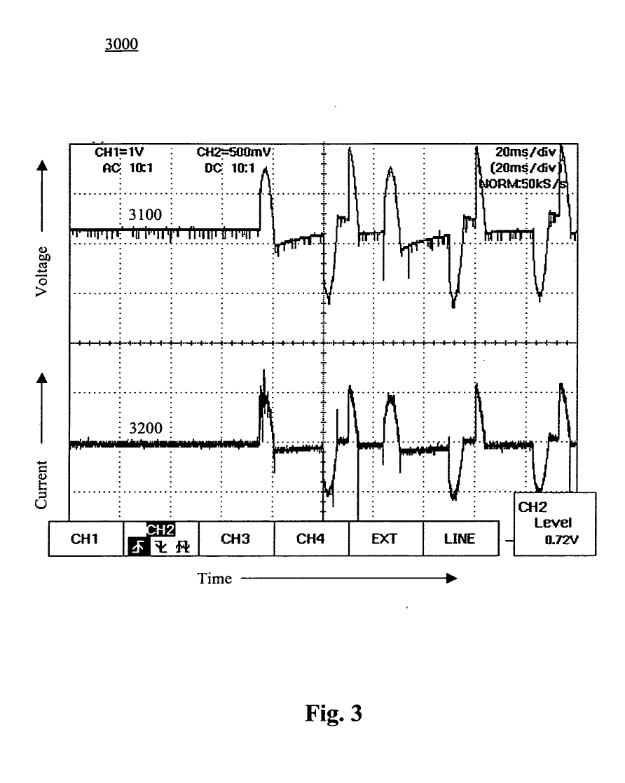

FIG. 3 is a graph 3000 of an exemplary current waveform 3200 and an exemplary voltage waveform 3100 that can be associated with arc fault signal conditioning circuit 2000 of FIG. 2. Current waveform 3200 can be a waveform associated with current sensor 2350 of FIG. 2 for a 75 amp point contact arc test. Voltage waveform 3100 can be associated with a voltage signal sent to an analog input of a microprocessor such as single-chip microprocessor 1100 of FIG. 1. Voltage waveform 3100 can be provided to an Analog to Digital converter. In generating voltage waveform 3100, a +3.3V power supply might be utilized. First exemplary voltage waveform 3100 can be characterized by an offset signal of approximately 3.3/2V. Voltage waveform can be sent to the microprocessor and/or a DSP through an Analog to Digital (A/D) converter for processing. Similar results can be generated under different predetermined DC voltages, such as for example approximately 25, 21.2, 15, 10.2, 8.5, 5, 3.9, 2.7, 1, and/or 0.5, etc. and/or any other value or subrange therebetween.

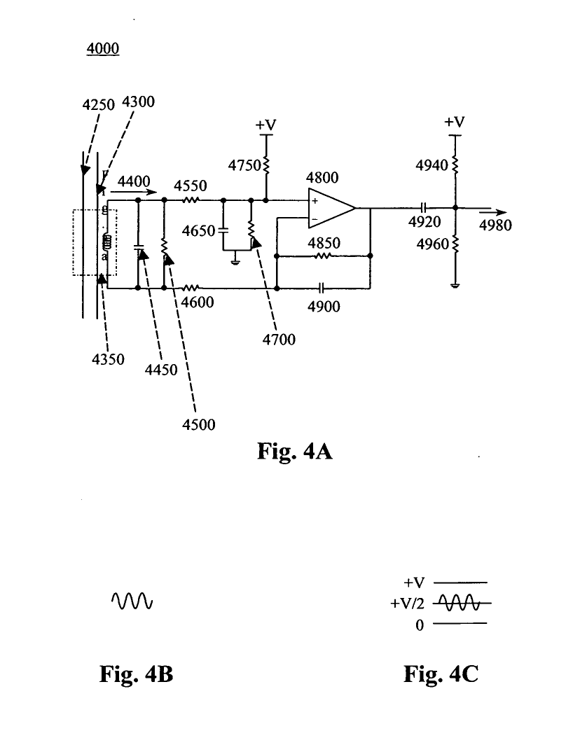

FIG. 4A is a block diagram of an exemplary embodiment of an electrical circuit 4000, which can be configured to condition of a signal monitored to detect a ground fault. Electrical circuit 4000 can comprise exemplary embodiments of differential current sensor 1500 and/or differential current conditioning circuit 1550 of FIG. 1. Electrical circuit 4000 can receive an input signal 4400 from a differential current sensor 4350, which can be characterized by an input waveform, such as an exemplary input signal as illustrated in FIG. 4A. Differential current sensor 4350 can determine a current differential between a line conductor 4250 and a neutral conductor 4300.

An output signal 4980 from electrical circuit 4000 can be characterized by an output waveform, such as an exemplary output signal as illustrated in FIG. 4C, which can be approximately centered in a predetermined DC voltage range. The output waveform can be configured to be transmitted to an input of a microprocessor and/or DSP. The microprocessor and/or DSP can comprise circuitry configured to perform an Analog to Digital (A/D) conversion upon output signal 4980. Electrical circuit 4000 can comprise a signal voltage amplifier 4800. Electrical circuit 4000 can be relatively simple and inexpensive to manufacture.

Electrical circuit 4000 can comprise a plurality of resistors such as resistor 4500, resistor 4550, resistor 4600, resistor 4700, resistor 4750, resistor 4850, resistor 4940, and/or resistor 4960, each of which can be selected and sized to set a gain of amplifier 4800, to match impedance from both positive and negative inputs of amplifier 4800, and/or to set an offset voltage of output signal 4980 into a center of the predetermined DC voltage range.

Electrical circuit 4000 can comprise a plurality of capacitors such as capacitor 4650 and/or capacitor 4900, which can be selected and/or sized to set a frequency response of electrical circuit 4000 to control a gain of a high frequency signal. The gain in the high frequency signal can be interpreted as noise by a ground fault detection algorithm. A capacitor 4920 can be selected and/or sized to provide a relatively low signal offset error. A digital square wave output from the microprocessor and/or DSP can be used to simulate a ground fault to test the function of a system comprising electrical circuit 4000 from amplifier 4800 to a mechanical tripping mechanism associated with electrical circuit 4000.

FIG. 4B is an exemplary ground fault signal conditioning circuit input waveform 4100.

FIG. 4C is an exemplary ground fault signal conditioning circuit output waveform 4200.

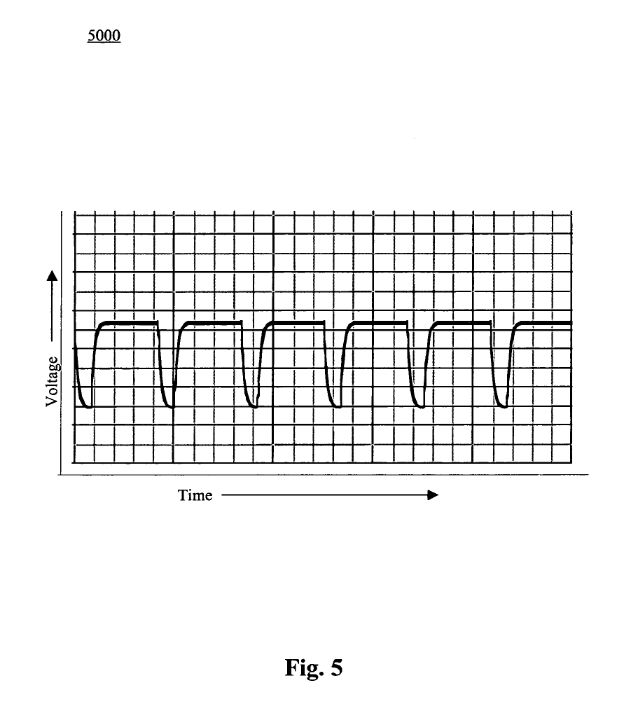

FIG. 5 is a graph 5000 of a simulated arc voltage waveform, which can be transmitted to a microprocessor or DSP, such as single-chip microprocessor 1100 of FIG. 1. The simulated arc waveform can be generated responsive to a user pressing a Push to Test Button. In certain exemplary embodiments, a reference point of an input signal to the microprocessor or DSP can be a middle point of a predetermined DC voltage range. Certain exemplary arc waveforms transmitted to the microprocessor and/or DSP can be pulsed at less than half of the predetermined voltage (such as at approximately 1.65V in certain exemplary embodiments). Amplitudes and shapes of certain exemplary pulses can be interpreted as arc events based on definitions in an arc detection algorithm

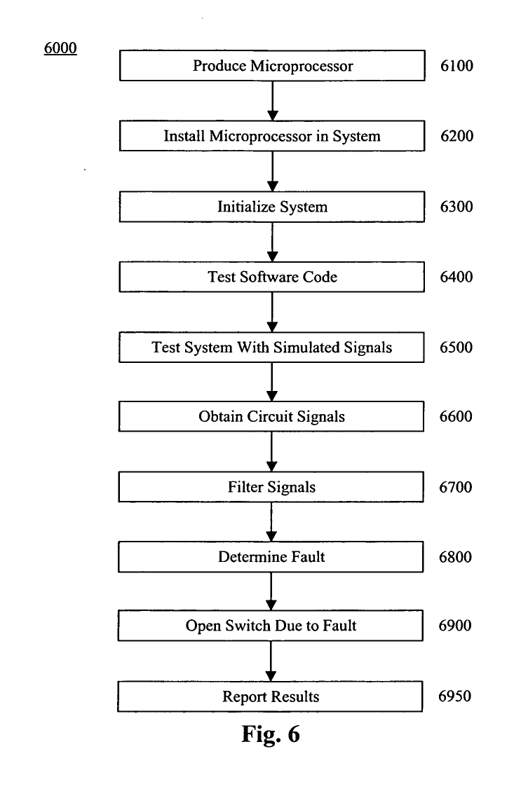

FIG. 6 is a flowchart of an exemplary embodiment of a method 6000. In certain exemplary embodiments, one or more activities comprised in method 6000 can be embodied on a machine-readable medium. The machine-readable medium can comprise machine instructions for one or more activities comprised in method 6000.

At activity 6100, a microprocessor can be designed and/or produced. The microprocessor can be a single-chip microprocessor and/or a single-chip digital signal processor (DSP). The microprocessor can be configured to determine, based upon one or more received signals, a presence of a ground fault and/or an arc fault. The microprocessor can be configured to automatically generate an output signal to an output pin responsive to an input signal indicative of an arc fault. The output signal can be configured to trip a circuit breaker, such as a single circuit breaker. The microprocessor can be configured to detect corruption in code comprised in the microprocessor. The code can be associated with the output signal. Certain exemplary microprocessors can comprise an on-chip resistive device configured to measure a temperature. The temperature can be utilized by the microprocessor to perform temperature compensation for one or more sensor readings associated with ground fault and/or arc fault determination.

The microprocessor can comprise and/or be electrically coupled to a Light Emitting Diode (LED). The LED can be configured to indicate a status of the microprocessor and/or a system comprising the microprocessor.

Variations in circuits comprised in the microprocessor, such as arc fault and/or ground fault signal input circuits can cause unanticipated results. A gain calibration can be used to at least partially compensate and/or correct such variations. The gain calibration can be conducted during production utilizing a test fixture. During gain calibration, relatively well defined signal sources can be provided to the arc fault and/or the ground fault input circuits. Probes from the test fixture can be used to send digital signals to input ports of the microprocessor for the gain calibration procedure. The gain calibration can be based in hardware, firmware, and/or software. Input values from Analog to Digital (A/D) converters can be compared with theoretical values. Arc fault and/or ground input circuits can process signals such that output values vary approximately linearly with input values. A ratio value can be obtained during calibration for each input circuit and saved in a nonvolatile memory device. Each ratio value can be used to correct values acquired through A/D inputs. In embodiments where gain calibration is not performed, default values based on one or more theoretical calculations can be used.

In certain exemplary embodiments, a temperature calibration can be performed to compensate temperature caused variations of sensors utilized as inputs for arc fault and/or ground fault detection. The temperature calibration can be configured to test input circuits comprised in the microprocessor. In certain exemplary embodiments, a temperature sensor can be utilized. A calibration can be performed for temperature compensation under a preset temperature, for example approximately 25 degrees Celsius. Temperature caused variation of sensed signals can be experimentally predetermined and/or predicted. After the temperature sensor is calibrated, the microprocessor can determine and/or estimate an approximate actual environmental temperature. Once a mathematical formula is established and/or predetermined values related to temperature compensation are stored, the microprocessor can be configured to provide temperature compensation for electrical measurements from one or more sensors.

At activity 6200, the microprocessor can be installed in a system configured to determine the presence of a ground fault and/or an arc fault. The system can comprise one or more current and/or differential current sensors configured to provide signals to the microprocessor. The system can comprise one or more conditioning circuits configured to condition signals from the one or more sensors prior to a transmission of the signals to the microprocessor.

At activity 6300, the system can be initialized. For example, the one or more sensors can be calibrated. In certain exemplary embodiments, the microprocessor can be configured to perform a self-test. The microprocessor can avoid providing a signal to open a switch to stop an electrical flow in an electrical circuit during a predetermined time period during which the self-test is being performed. In certain exemplary embodiments, a determination can be made regarding a status of the switch. One or more signals indicative of a status of the switch can be provided as an input to the microprocessor or DSP.

At activity 6400, software code can be tested to detect code corruption. The software code can be stored in a memory device. Verifying an absence of code corruption can relatively enhance system software stability. The software code can be tested potentially at any time, such as aperiodically and/or periodically at a predetermined frequency.

At activity 6500, system performance can be tested via one or more simulated signals. For example, the one or more simulated signals can comprise a signal indicative of an arc fault and/or a signal indicative of a ground fault. The system test can comprise checking a switch status and sending out a signal characterized by a simulated arc waveform to test the arc fault circuit. The test can be configured to determine if an arc signal input opens the switch via an electrically and/or mechanically coupled trip mechanism. The test can be performed potentially at any time, such as aperiodically and/or periodically at a predetermined frequency. When the test is performed the system can be configured not to process and/or respond to variations in one or more circuit signals.

The simulated arc waveform can comprise a series of approximately rectangle pulses. In certain exemplary embodiments, the pulses can comprise between approximately 4 and 8 pulses within a time period of approximately 500 milliseconds. In certain exemplary embodiments, the pulses can be characterized by a frequency of approximately 60 Hertz and a duty cycle of approximately 70%. An exemplary embodiment of a simulated arc fault waveform is illustrated in FIG. 5.

At activity 6600, an arc fault or ground fault signals can be obtained from sensors configured to measure an electric current and/or a differential current. A conditioning circuit can process each obtained signal prior to transmission to the microprocessor. The signals can be processed via an A/D converter circuit, which can be comprised in the microprocessor.

At activity 6700, signals can be filtered. Signals output from an A/D converter can be processed with a digital filtering algorithm for relatively good noise immunization. In embodiments where calibrations have been performed, signals can be corrected and/or compensated based on results of calibrations. In embodiments where calibrations were not performed, default values can be used in signal processing.

At activity 6800, a filtered and/or calibrated waveform can be processed by an algorithm for arc and ground detection comprised in the microprocessor.

At activity 6900, if an arc or ground fault is detected, a SCR triggering signal can be transmitted via a digital output port. The signal can be configured to disconnect system power to an electrical circuit via a solenoid controlled mechanical mechanism. If no fault is detected, method 6000 can be recursively executed to attempt to detect a fault.

At activity 6950, results can be reported. For example, if code corruption is detected, information regarding the corruption can be transmitted and/or reported to one or more users via one or more I/O devices and/or information devices associated and/or communicatively coupled to the microprocessor. If a fault is detected and/or a circuit breaker associated with the microprocessor is tripped, information regarding the fault can be transmitted and/or reported to one or more users via the one or more I/O devices and/or information devices.

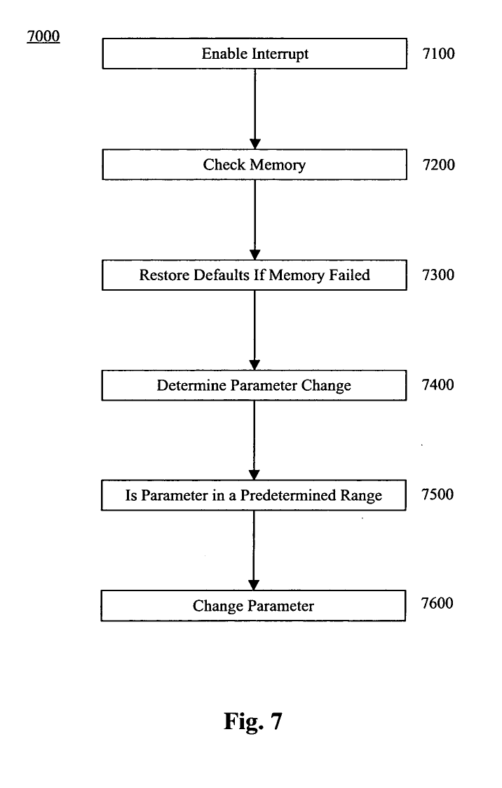

FIG. 7 is a flowchart of an exemplary embodiment of a method 7000. At activity 7100, an interrupt associated with a microprocessor configured to detect faults in an electrical circuit can be enabled. Certain exemplary embodiments can comprise a watchdog timer, which can be configured to reset a software process responsive to a determination that the software process is not performing in an expected manner. A watchdog counter associated with the watchdog timer can be sequentially incremented and tested to determine if a predetermined threshold has been exceeded. The watchdog counter can be reset responsive to one or more predetermined criteria configured to determine a proper operation of the software process.

In certain exemplary embodiments, a timer based interrupt rate can be relatively fast, such as less than approximately 120 microseconds. This rate is too high to make the rate apparent if an LED associated with the microprocessor were switched each time when an interrupt routine is executed. In certain exemplary embodiments, a software counter can be used to reduce a blinking rate of the LED to a visible rate, such as between approximately 10 and approximately 25 times/second.

At activity 7200, a memory device associated with the microprocessor can be checked. For example, the memory device can be checked to determine if software code has been corrupted. For example, a flash memory can be tested to determine if a location in the flash memory and/or data comprised in the location in the flash memory is an expected value. An unexpected value or result from the location in the flash memory can be indicative that software code has been corrupted.

At activity 7300, default values can be restored if a determination is made that the software code has been corrupted and/or the memory device has failed. In certain exemplary embodiments, the default values can be rendered for viewing by a user.

At activity 7400, a determination can be made of whether one or more parameters have changed. The determination that one or more parameters have changed can be made via a Cyclic Redundancy Check (CRC). If the cyclic redundancy check fails, certain exemplary embodiments can provide instructions to launch the watchdog timer without resetting the watchdog counter.

At activity 7500, a determination is made whether a parameter is within a predetermined range.

At activity 7600, a parameter can be changed responsive to a determination that the parameter is outside the predetermined range. In certain exemplary embodiments, if a parameter has changed and is outside of a predetermined range, the change of the parameter can be ignored and the parameter restored to a prior value. If the parameter is within the predetermined range, one or more input signals can be tested to determine whether each input is within a predetermined range. If an input is out of range, the input can be set to a minimum value.

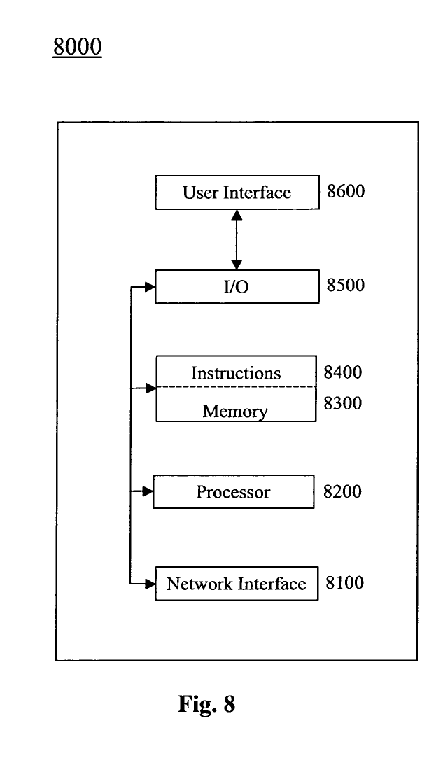

FIG. 8 is a block diagram of an exemplary embodiment of an information device 8000, which in certain operative embodiments can comprise, for example, information device 1970, of FIG. 1. Information device 8000 can comprise any of numerous components, such as for example, one or more network interfaces 8100, one or more processors 8200, one or more memories 8300 containing instructions 8400, one or more input/output (I/O) devices 8500, and/or one or more user interfaces 8600 coupled to I/O device 8500, etc.

In certain exemplary embodiments, via one or more user interfaces 8600, such as a graphical user interface, a user can view a rendering of information related to arc fault and/or ground fault detection in an electrical circuit.

Still other practical and useful embodiments will become readily apparent to those skilled in this art from reading the above-recited detailed description and drawings of certain exemplary embodiments. It should be understood that numerous variations, modifications, and additional embodiments are possible, and accordingly, all such variations, modifications, and embodiments are to be regarded as being within the spirit and scope of this application.

Thus, regardless of the content of any portion (e.g., title, field, background, summary, abstract, drawing figure, etc.) of this application, unless clearly specified to the contrary, such as via an explicit definition, assertion, or argument, with respect to any claim, whether of this application and/or any claim of any application claiming priority hereto, and whether originally presented or otherwise:
there is no requirement for the inclusion of any particular described or illustrated characteristic, function, activity, or element, any particular sequence of activities, or any particular interrelationship of elements;
any elements can be integrated, segregated, and/or duplicated;
any activity can be repeated, performed by multiple entities, and/or performed in multiple jurisdictions; and
any activity or element can be specifically excluded, the sequence of activities can vary, and/or the interrelationship of elements can vary.

Accordingly, the descriptions and drawings are to be regarded as illustrative in nature, and not as restrictive. Moreover, when any number or range is described herein, unless clearly stated otherwise, that number or range is approximate. When any range is described herein, unless clearly stated otherwise, that range includes all values therein and all subranges therein. Any information in any material (e.g., a United States patent, United States patent application, book, article, etc.) that has been incorporated by reference herein, is only incorporated by reference to the extent that no conflict exists between such information and the other statements and drawings set forth herein. In the event of such conflict, including a conflict that would render invalid any claim herein or seeking priority hereto, then any such conflicting information in such incorporated by reference material is specifically not incorporated by reference herein.

What is claimed is:

1. A fault detection system comprising:
a single-circuit breaker dedicated microprocessor configured to:
automatically generate an output signal to an output pin responsive to an input signal indicative of an arc fault, said output signal configured to trip a single circuit breaker; and
detect corruption in code comprised in said microprocessor, said code associated with said output signal.

2. The system of claim 1, further comprising:
a light emitting diode indicator configured to indicate a run status of said microprocessor

3. The system of claim 1, further comprising:
a resistive current sensor electrically coupled to said microprocessor.

4. The system of claim 1, further comprising:
a differential current sensor electrically coupled to said microprocessor.

5. The system of claim 1, further comprising:
a device configured to trip an electrical circuit associated with said fault detection system.

6. The system of claim 1, further comprising:
a temperature sensor configured to provide a temperature value for correcting a measured value of a current sensor electrically coupled to said microprocessor.

7. The system of claim 1, further comprising:
a temperature sensor configured to provide a temperature value for correcting a measured value of a current sensor electrically coupled to said microprocessor; and
an analog to digital converter configured to accept an analog input from said current sensor and provide a digital output to said microprocessor.

8. The system of claim 1, further comprising:
an amplifier configured to amplify an analog signal from a current sensor, said amplifier electrically coupled to said microprocessor.

9. The system of claim 1, further comprising:
an analog to digital converter configured to accept an analog input from a current sensor electrically coupled to said microprocessor and provide a digital output to said microprocessor.

10. The system of claim 1, further comprising:
an analog to digital converter configured to accept an analog input from a differential current sensor and provide a digital output to said microprocessor.

11. The system of claim 1, further comprising:
a power supply configured to provide electrical energy to said microprocessor.

12. The system of claim 1, further comprising:
a plurality of resistors configured to set a gain of an amplifier comprised in said fault detection system and set a signal output of said amplifier at a predetermined level in a predetermined direct current voltage range before said signal output is received by an analog to digital converter.

13. The system of claim 1, said microprocessor further configured to:
provide a simulated arc fault signal to test said fault detection system.

14. The system of claim 1, said microprocessor further configured to:
automatically calibrate a current sensor and a differential current sensor comprised in said fault detection system.

15. The system of claim 1, said microprocessor further configured to:
receive a user request to calibrate a current sensor and a differential current sensor electrically coupled to said microprocessor.

16. The system of claim 1, said microprocessor further configured to:
provide a simulated signal indicative of a ground fault to test said fault detection system.

17. The system of claim 1, said microprocessor further configured to:
receive said input signal indicative of an arc fault from a current sensor electrically coupled to said microprocessor.

18. The system of claim 1, said microprocessor further configured to:
receive a signal indicative of a ground fault from a differential current sensor electrically coupled to said microprocessor.

19. The system of claim 1, said microprocessor further configured to:
automatically calibrate a gain of an analog to digital converter electrically coupled to a current sensor electrically coupled to said microprocessor.

20. The system of claim 1, said microprocessor further configured to:
automatically correct a value obtained from a current sensor electrically coupled to said microprocessor based upon a measured temperature.

21. The system of claim 1, said microprocessor further configured to:
automatically correct a value obtained from a differential current sensor electrically coupled to said microprocessor based upon a measured temperature.

22. A method comprising:
configuring a microprocessor to.
automatically generate an output signal to an output pin responsive to an input signal indicative of an arc fault, said output signal configured to trip a single circuit breaker; and
detect corruption in code comprised in said microprocessor, said code associated with said output signal.

23. A machine-readable medium comprising machine instructions for activities comprising:
automatically generating an output signal to an output pin responsive to an input signal indicative of an arc fault, said output signal configured to trip a single circuit breaker; and
detecting corruption in code comprised in a microprocessor, said code associated with said output signal.
